(19) United States
(12) Patent Application Publication
(10) Pub. No.: US 2009/0038783 A1
(43) Pub. Date: Feb. 12, 2009

(54) COMPUTER COOLING CASE OF NEGATIVE PRESSURE SUCKING TYPE

(76) Inventor: Yung-Hao CHEN, Chung-Ho City (TW)

Correspondence Address: HDSL, P.O. BOX 220746, CHANTILLY, VA, 20153-0746, US

(21) Appl. No.: 11/870,494

(22) Filed: Oct. 11, 2007

(30) Foreign Application Priority Data
Aug. 8, 2007 (TW) 096213055

(51) Int. Cl. F28F 13/12; H05K 7/20

(52) U.S. Cl. 165/122; 361/687

(57) ABSTRACT

A computer cooling case includes a computer case and a plurality of fans. Each fan is for exhausting air in the computer case to the outside. During operation, a negative pressure is created in the computer case to define a zone to be cooled. A plurality of intakes are arranged on one side of the computer case in the neighborhood of the zone to be cooled. An air-guiding passage is arranged from each intake to the zone to be cooled. When each fan is operated, since the computer case is under a negative pressure state, outside air may be sucked in through each intake and then guided to each zone to be cooled for undertaking a cooling process.

### BACKGROUND OF THE INVENTION

1. Field of the Invention

The present invention generally relates to a computer, in particular, to a case of host computer, which can provide a further cooling function.

2. Description of Prior Art

Following the progress of technology, the executing speed of computer becomes faster and faster, making the temperature generated in a host computer become higher and higher. In order to dissipate the heat generated in the host computer to keep each element therein operated under tolerable temperature, cooler with large size is usually attached onto highly heat-dissipating element for undergoing a cooling effect.

In addition, since most prior cooler structures have been applied to CPU (Central Processing Unit) already, other cooling issues are increasingly emphasized in the current computer elements, such as, VGA card. Besides, since current computer all needs the operational support of multimedia and due to a rise in game software, the use of each kind of expansion card will generate a heat sink as well. In particular, if the heat generated from a graphics chip (e.g. VGA card) is not dissipated, then an overheating problem that influences the PC operation will be probably annoyed. Because computer case is an almost airtight space and it is uneasy to exhaust heat to the outside, a similar greenhouse effect is often occurred therein to deteriorate the operation efficiency.

Currently, there is one solution existed; i.e., a fan is additionally arranged on the computer case, aiming to dissipate the heat generated from the graphics chip on the VGA card. However, this solution not only increases the quantity of applying fans, but also creates too much noise because of the increase of using fans. If a natural convection is created by the provision of other fans, the number of using fan as well as the noise can be reduced.

Accordingly, aiming to solve aforementioned shortcomings, after a substantially devoted study, in cooperation with the application of relatively academic principles, the inventor finally proposes the present invention that is designed reasonably to possess the capability to improve the prior arts significantly.

### SUMMARY OF THE INVENTION

The invention is mainly to provide a computer cooling case of negative pressure sucking type. The case may create a negative pressure therein to automatically suck in airflow from the intakes arranged at one side of the case. This airflow may provide a cooling effect to a specific zone in the case, in particular, to the processing chip on a VGA card.

The invention is to provide a computer cooling case of negative pressure sucking type, which includes a hollow computer case and a plurality of fans, each of which is arranged on the computer case and is for exhausting air in the computer case to the outside. During operation, a negative pressure is created in the computer case to define a zone to be cooled. A plurality of intakes are arranged on one side of the computer case in the neighborhood of the zone to be cooled. An air-guiding passage is arranged from each intake to the zone to be cooled. Thereby, when each fan is operated, since the computer case is under a negative pressure state, outside air may be sucked in through each intake and then guided to each zone to be cooled for undertaking a cooling process.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1 is an explosive illustration of the case interior of the present invention;

FIG. 2 is an assembled illustration of the case interior of the present invention;

FIG. 3 is a longitudinal section of the case interior of the present invention;

FIG. 4 is a cross section of the case interior of the present invention;

FIG. 5 is an explosive illustration of the case interior of the present invention from another viewing angle;

FIG. 6 is an assembled illustration of the case interior of the present invention from another viewing angle; and

FIG. 7 is a partially enlarging view of “A”-part in FIG. 6.

### DETAILED DESCRIPTION OF THE INVENTION

In cooperation with attached drawings, the technical contents and detailed description of the present invention are described thereinafter according to a preferable embodiment, being not used to limit its executing scope. Any equivalent variation and modification made according to appended claims is all covered by the claims claimed by the present invention.

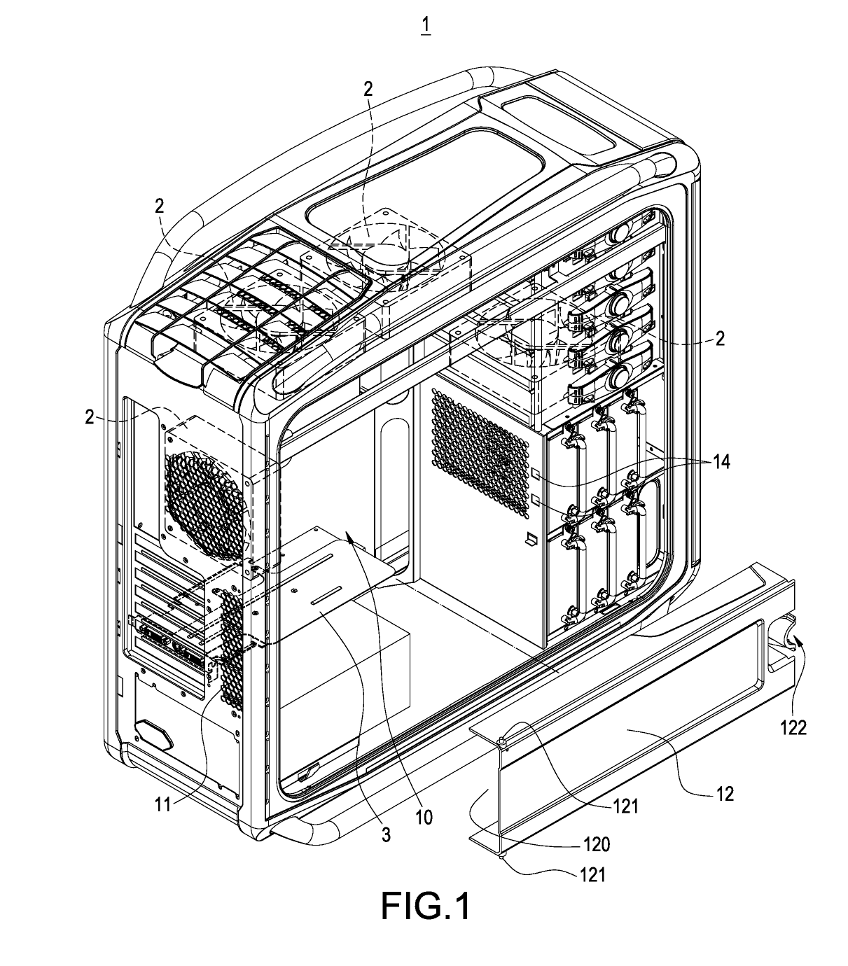

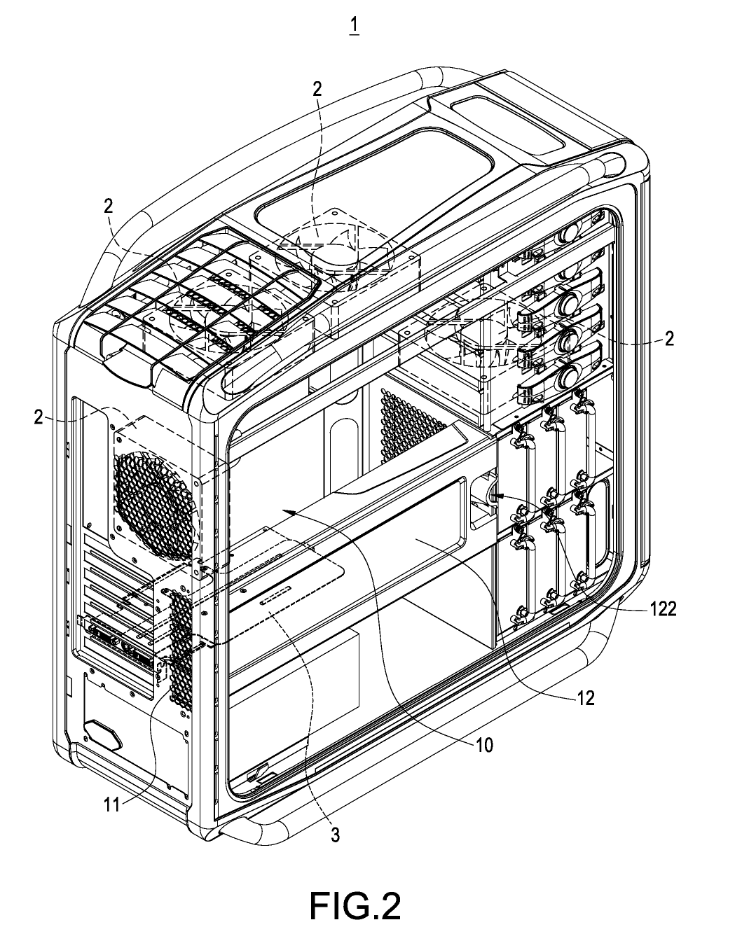

Please refer to FIG. 1 and FIG. 2, which respectively are an explosive illustration and an assembled illustration of the case interior of the present invention. The invention is mainly to provide a computer cooling case of negative pressure sucking type, which includes a plurality of fans 2, each of which is arranged on a computer case 1 and adopts air-sucking type (i.e., from the outside to the inside) to thereby exhausting the air in the computer case 1 to the ambience. Since a negative pressure is formed in the computer case 1, outside air may be guided to the object to be cooled, for example, the processing chip on a VGA card 3, through the intakes 11 on the computer case 1.

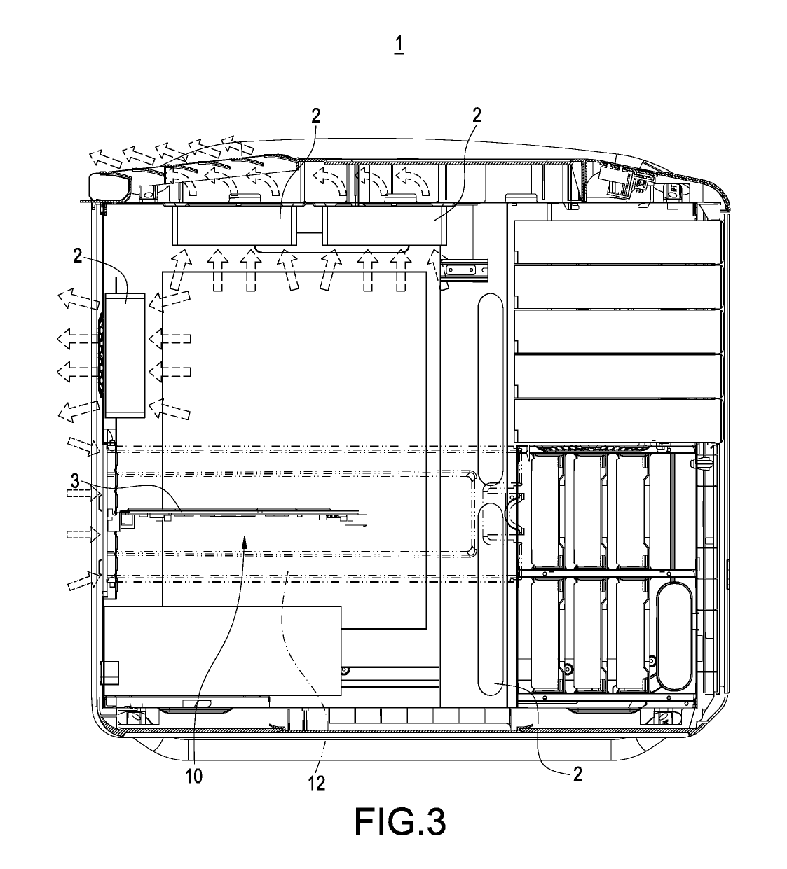

The hollow space in the computer case 1 is provided for each element to be arranged therein, for example, the motherboard, the hard disk, and the power supply, etc., which are belong to prior arts, so detailed description is not repeated herein. Each fan 2 is disposed at appropriate position on the side of the computer case 1, for example, the upper, lower sides or the front, rear side, according to space size designed for the computer case 1. The larger the internal space of the computer case is designed, the more the number of the fans 2 is needed, or the larger the ventilation of a single fan 2 is provided, and vice versa. Through the operation of each fan 2, a negative pressure is generated in each zone to be cooled, such that the hot air in the computer case 1 may be exhausted to the ambience, as shown in FIG. 3.

According to the present invention, the interior of the computer case 1 at least has a heating zone 10 specifically chosen as the zone to be cooled, in the neighborhood of which a plurality of intakes 11 are arranged on one side of the computer case 1 and are followed or connected by a air-guiding passage 120, which is extended from one side of the computer case 1 toward the heating zone 10. According to a preferable embodiment of the present invention, the heating zone 10 is denoted to a specific position, where a cooling treatment is provided to a VGA card 11 arranged on a computer motherboard, while the intakes 11 are arranged on the rear side of the computer case 1 and are connected to the heating zone 10 through an air-guiding hood 12, the cross section of which is shown as a “C”-shape, and in which an air-guiding passage 120 is formed, such that, when the air-guiding hood 12 is placed in the computer case 1 horizontally, the air-guiding passage 120 may be just extended to the heating zone 10.

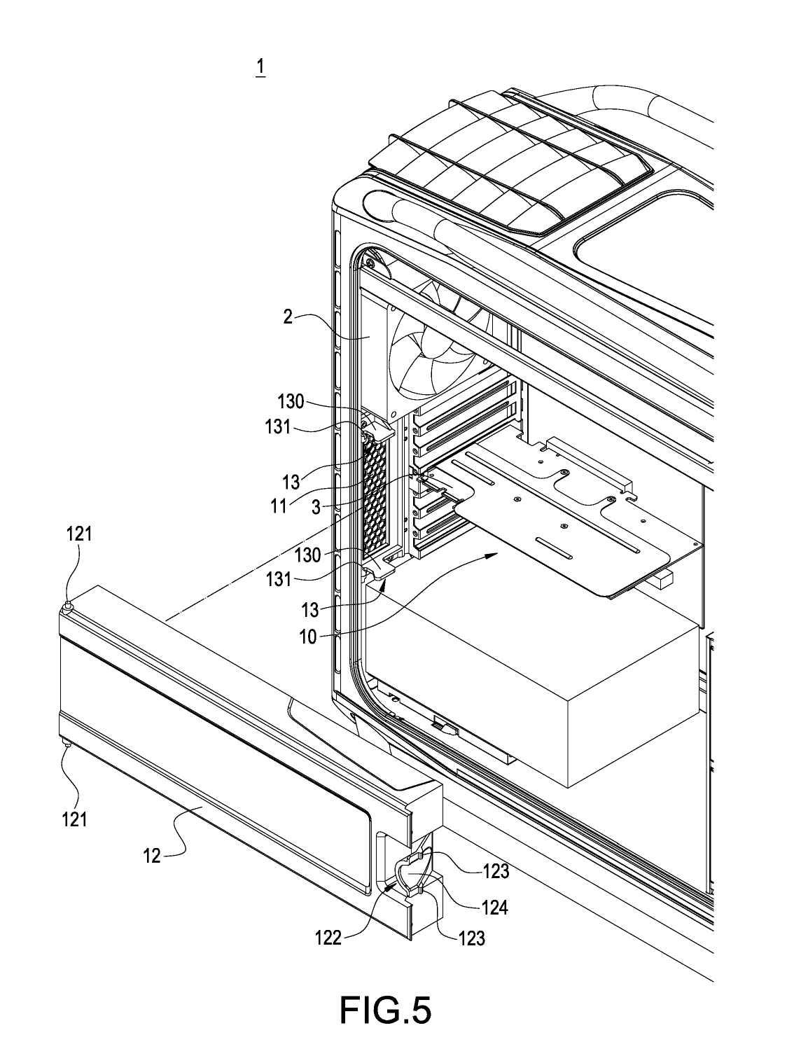

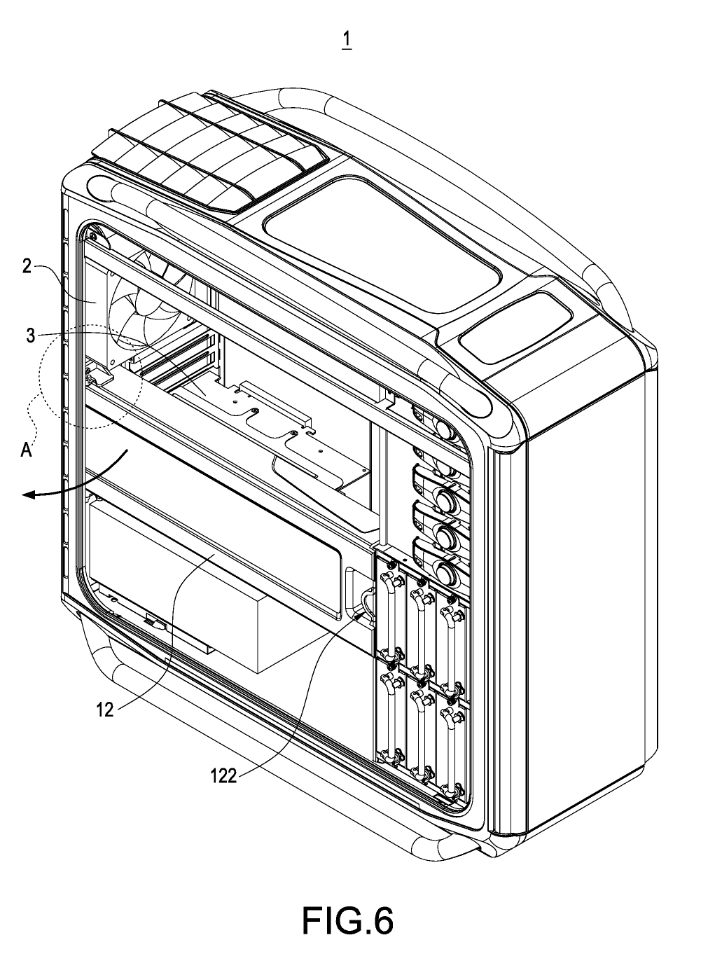

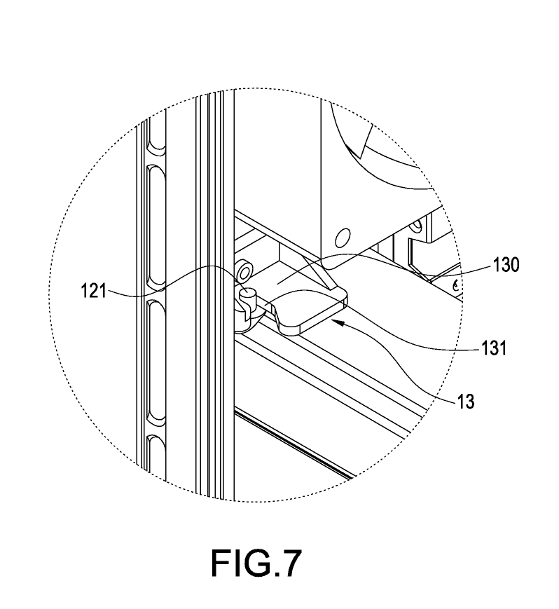

Furthermore, as shown in FIG. 5 and FIG. 6, a pivot 121 is arranged at one side of the air-guiding hood 12 near the intake 11, while another side is arranged a leaf spring 122. A pivoting part 13 is arranged at the computer case 1 in corresponding to the pivot 121, while a buckling hole 14 is also arranged in corresponding to the leaf spring 122, as shown in FIG. 1. In this case, the pivoting part 13 of the computer case 1 is constructed by two upright boards 130 interspaced to each other, the distance between which is just identical to the width of the air-guiding hood 2. As shown in FIG. 7, a pivoting groove 131 is respectively arranged at the upright boards 130 for providing the pivot 121 to be glided in, thereby the air-guiding hood 12 being able to be pivoted to the pivoting part 13. On the other hand, the leaf spring 122 of the air-guiding hood 12 is arranged a projected buckling part 123 capable of being buckled in the buckling hole 14. A pulling arc opening 124 may be further formed by making a recess to the leaf spring 122, thereby a human thumb being able to abut against the leaf spring 122 to apply a pulling force. When the leaf spring 122 is being pulled, it is possible to lift up the air-guiding hood 12 toward one side of the computer case, thereby the parts in the computer being able to be arranged and maintained.

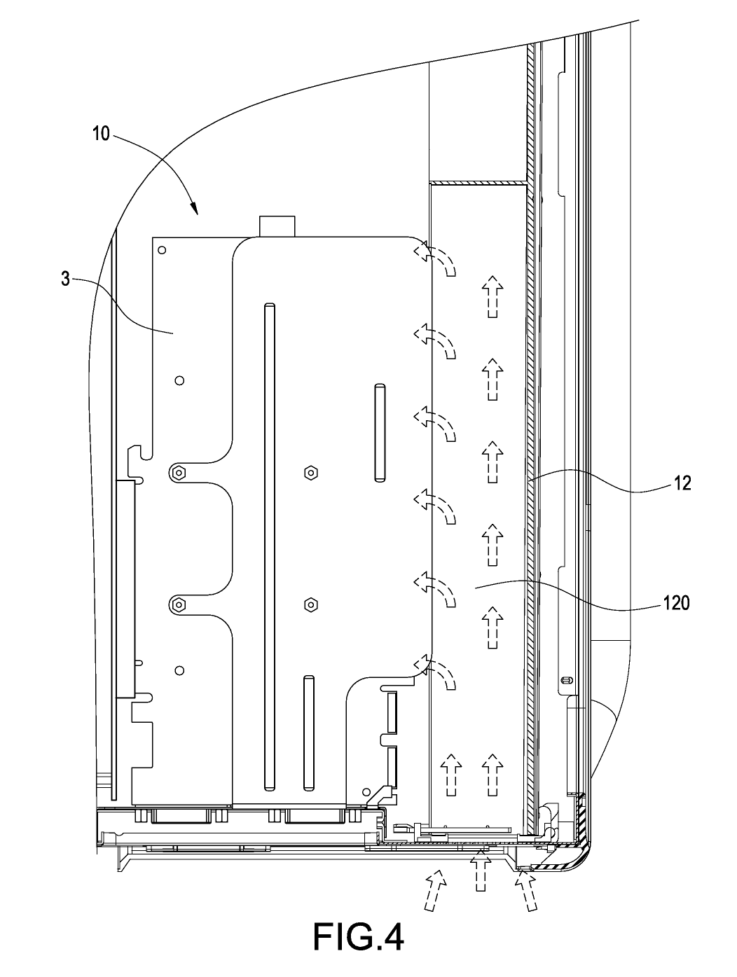

Accordingly, please refer to FIG. 3 and FIG. 4 together. Since each fan 2 may suck out the hot air of each interior in the computer case 1, a negative pressure is created therein and respectively. Thereby, ambient air may actively enter the computer case 1 through the intakes 11 and is further guided to the heating zone 10 through the guidance of the air-guiding passage 120 of the air-guiding hood 2 to finally provide the cooler an airflow needed by the heating zone 10 to continuously dissipate the heat generated therein to avoid the accumulation of heat caused by the greenhouse effect, because ambient air with low temperature keeps on flowing into the computer case 1 through this sucking effect of negative pressure created by abovementioned structure proposed by the invention.

Therefore, the computer cooling case of negative pressure sucking type according to the invention not only may help the interior of the computer case 1 make airflow exchange through the operation of each fan, but also may provide a cooling airflow passage to automatically suck in ambient air after a negative pressure state in the computer case 1 is created by the ventilating effect of each fan, thereby capable of providing a specific cooling effect to any specific zone or position in the computer case 1, in particular, to the processing chips on a VGA card without an exclusive arrangement of fan and with a reduction of noise to possess an effect of silence.

Summarizing aforementioned description, the invention is an indispensable product of novelty indeed, which may positively reach the expected usage objective for solving the drawbacks of the prior arts, and which extremely possesses the innovation and progressiveness for completely fulfilling the applying merits of new type patent, according to which the invention is thereby applied. Please examine the application carefully and grant it as a formal patent for protecting the rights of the inventor.

However, the aforementioned description is only a preferable embodiment according to the present invention, being not used to limit the patent scope of the invention, so equivalently structural variation made to the contents of the present invention, for example, description and drawings, is all covered by the claims claimed thereinafter.

What is claimed is:

1. A computer cooling case of negative pressure sucking type, including:
a computer case, having an hollow interior and a zone being defined to be cooled; and
a plurality of fans, each of which is arranged on the computer case for exhausting inside air to ambience and making the interior of the computer case become a negative pressure state;
wherein a plurality of intakes are arranged in a neighborhood of the zone to be cooled on one side of the computer case and are followed by an air-guiding passage for connection to the zone to be cooled; wherein, when a plurality of fans are operated, a negative pressure is created in the computer case to make ambient air sucked in through the intakes and guided to the zone to be cooled through the air-guiding passage for facilitating the cooling process.

2. The computer cooling case of negative pressure sucking type according to claim 1, wherein the zone to be cooled is a heating zone.

3. The computer cooling case of negative pressure sucking type according to claim 2, wherein a VGA card is arranged in the heating zone.

4. The computer cooling case of negative pressure sucking type according to claim 1, wherein the intakes are arranged on a rear side of the computer case.

5. The computer cooling case of negative pressure sucking type according to claim 1, wherein the air-guiding passage is formed as a “C”-profile in an air-guiding hood.

6. The computer cooling case of negative pressure sucking type according to claim 5, wherein a pivot is arranged at one side of the air-guiding hood, while a leaf spring is arranged at another side, a pivoting part being arranged at the computer case in corresponding to the pivot and a bucking hole being arranged at the computer case in corresponding to the leaf spring, the pivot being pivoted to the pivoting part and a projected buckling part being arranged on the leaf spring for being snapped into the buckling hole.

7. The computer cooling case of negative pressure sucking type according to claim 6, wherein the pivoting part is constructed by two upright boards interspaced to each other, a distance between which is matched to a width of the air-guiding hood, and on which a pivoting groove is respectively arranged for providing the pivot to be glided therein for facilitating a pivoting operation.

8. The computer cooling case of negative pressure sucking type according to claim 5, wherein a pulling arc opening is formed by making a recess on the leaf spring to facilitate a human thumb abutting upon the leaf spring to apply a force.

9. The computer cooling case of negative pressure sucking type according to claim 1, wherein the fans are respectively arranged at an upper side and a lower side of the computer case.

10. The computer cooling case of negative pressure sucking type according to claim 9, wherein the fans are respectively arranged at a front side and a rear side of the computer case.

11. The computer cooling case of negative pressure sucking type according to claim 1, wherein the fans are respectively arranged at a front side and a rear side of the computer case.
